(19) United States
(12) Patent Application Publication
(10) Pub. No.: US 2007/0101303 A1
(43) Pub. Date: May 3, 2007

(54) Method and apparatus for integrated circuit layout optimization

(75) Inventors: Jung-Cheun Lien, San Jose, CA (US); Minchen Zhao, Palo Alto, CA (US)

Correspondence Address: BIRCH STEWART KOLASCH & BIRCH, PO BOX 747, FALLS CHURCH, VA, 22040-0747, US

(73) Assignee: LIZOTECH, INC.

(21) Appl. No.: 11/590,840

(22) Filed: Nov. 1, 2006

Related U.S. Application Data
(60) Provisional application No. 60/733,732, filed on Nov. 3, 2005.

(51) Int. Cl. G06F 17/50; G03F 1/00; G21K 5/00

(52) U.S. Cl. 716/5; 716/10; 716/21; 430/5; 378/35

(57) ABSTRACT

A method and apparatus for integrated circuit layout optimization are provided. In the conventional art, the major challenges in building integrated circuits (IC) at sub-wavelength geometries include i) to ensure the design intent is faithfully transferred onto silicon; ii) to ensure the design is manufacturable, or with acceptable yield subject to process variations. The present invention provides the method to process a layout database to optimize or correct or fix layout violations or enhancements. The layout violations are identified through various means such as design rules, recommended rules, timing/signal integrity/power constraints, lithography rules, Resolution Enhancement Technologies (RET) requirements and preferences, and process and manufacturing constraints. Particularly, the method, techniques and procedures of creating software tools of the present invention used to perform the layout violations or enhancements are disclosed.

### CROSS REFERENCE TO RELATED PROVISIONAL APPLICATION

This application claims the benefit under 35 USC 119(e) of U.S. Provisional Application No. 60/733,732, filed Nov. 3, 2005, the contents of all of which are incorporated herein in their entirety.

### BACKGROUND OF THE INVENTION

1. Field of the Invention

The present invention relates to a method and an apparatus for integrated circuit layout optimization, more particularly, a software tool is used to optimize the routing design by means of a layout database.

2. Description of Related Art

### BACKGROUNDS

(1) Introduction to IC Routing Problem

An integrated circuit (IC) usually consists of a functional portion and an interconnect portion. The functional portion includes a set of functional elements which can be transistors, logic gates or functional blocks. The interconnect portion includes a set of metal wires and vias that connect the input and output terminals of functional elements to form the intended function of the circuit. To implement an IC, a designer must suitably place all functional elements, which can be in millions of gates, and route all the required connections specified in a netlist. To ensure the layout circuit works properly, the designer must do various analyses such as timing, signal integrity and power consumption on the circuit. A layout database must be adopted to pass so-called physical verification such as Design Rule Checks (DRC) before being signed-off and sent to mask shop for manufacturing. Usually, EDA (Electronic Design Automation) tools are available to help designers do these tasks automatically.

For circuits implemented in advanced process technology (0.13 um and below), the layout database must go through RET (Resolution Enhancement Technologies) steps before sending it to the mask shop. The most common step in RET is called Optical Proximity Correction (OPC), where small geometries are added to the layout to ensure that the intended design shapes are projected onto the wafer as closely as possible.

After that, a router can connect all terminals specified in a placed netlist automatically. To connect all terminals of a given net, the router can use either one or more routing layers. The routing layers usually are metals. Switching between routing layers can be done by using vias. One or more vias can be inserted to allow signal to switch from one layer to any other layer. It's possible for a terminal signal to go through several layers to reach its destination. There also exists areas called blockage that router must avoid. The blockage can also be in one or more routing layers. Design rules are used to guide the use of vias, blockage, metal lines width, length and spacing among them. Metal pitch refers to how close two metal lines can run in parallel. A complete routing not only has to finish all required connection specified in the netlist but also have to ensure the result is DRC clean.

Routers can be classified into two types, namely grid or gridless depending on whether a routing grid system is followed in the routing process. A grid router imposes a two dimensional grid system on routing layers, and all vias and metal lines used by the router are on the grid. In contrast, the gridless router doesn't assume such a routing grid, and the gridless router runs two metal lines at any spacing as long as the design rules are met. It is obvious that the grid router can run much faster than gridless router due to its limited searching space.

(2) Layout Violations

A layout design is usually required to satisfy many conditions including but not limited to area, width, length, overlap, spacing density and via doubling. These conditions are usually targeted at various aspects of IC design such as design rules, recommended rule, timing, signal integrity, power, OPC/RET and lithography rules, yield and manufacturability.

According to the importance of a layout violation, each layout violation can be assigned a weight. The weight number is assigned such that the higher the weight number, the more important to optimize/correct/fix such a violation. Also when we discussing the removal of layout violations herein, we use the words optimization, correction, fix interchangeably.

Each layout violation can also be assigned a cost to optimize/correct/fix. The cost represents effort/area/time to remove a violation. It is advantageous to optimize/correct/fix layout violations of a design such that the total weight is maximal and the total cost is minimal.

(3) EXAMPLES

FIG. 1 illustrates an example of an IC layout 100. The layout shown in the figure includes five circuit modules 105, 110, 115, 120, and 125 with pins 130, 135, 140, 145, 150, 155 and 160. More, four interconnect lines 165, 170, 175 and 180 connect above modules (105, 110, 115, 120, and 125) through their pins (105, 110, 115, 120, and 125). In addition, three nets specify the interconnection between the pins. Specifically, the pins 135, 145, and 160 define a three-pin net, while the pins 130 and 155, and the pins 140 and 150 respectively define two two-pin nets.

Essentially, routing is a key operation in the physical IC design cycle. It is generally divided into two phases, that are global routing and detailed routing. For each net, the global routing generates a path or routing areas for the interconnect lines that are to connect the pins of the net. After the global routes have been created, the detailed routing creates the specific individual routing paths for each net.

Furthermore, please refer to FIGS. 2 and 3, which illustrate two layers of 16 partitions of an IC region. The each sub-region has pins, virtual pins, and obstacles on the two layers. As shown in FIG. 2, two obstacles 21, 22 and port geometries 23, 24, 25, 26 and 27 are included, and the obstacles and port geometries can have a variety of shapes. On the periphery, the virtual pins 201, 203 and 205 are included. In the other layer as shown in FIG. 3, a virtual pin 301 and a obstacle 32 are included.

### RELATED ART

Reference is made to a conventional method for pre-computing routes for multiple wiring models of U.S. Pat. No. 6,687,893. The method initially defines a set of partitioning lines for partitioning the region into a plurality of sub-regions during a routing operation. For example, the method then identifies a first set of routes based on a first wiring model and a second set of routes based on a second wiring model. As illustration in this art, a routing process hierarchically defines routes for nets within a design region of an IC layout. The process initially defines a partitioning grid that divides the IC region into several sub-regions.

Referring to U.S. Pat. No. 6,957,408, a conventional method for routing nets in an integrated circuit layout is disclosed. The detail-routing process thereof defines the detailed routes for nets within a region of the IC layout. This region can be the entire IC layout, or a portion of this layout. Initially, this process selects a sub-region of the IC layout region to detailed route. Next, for each particular net in the selected sub-region, the process identifies a topological route that connects the particular net's routable elements in the sub-region. The net's routable elements can be the port geometries, and a net is routed along one port of each of its pins. Particularly, the topological route is a route that is defined in terms of some layout items, such as pins, obstacles, boundaries, and/or other topological routes of other nets.

After that, the process determines whether the identified topological routes are geometrically routable. If the process determines the identified topological routes for some of the nets are not routable, it will direct the topological router to generate additional topological routes that have design rule-correct geometric routes. Next, the process generates these geometric routes and stores these routes in a detail-routing storage structure. The process also converts the generated geometric detail routes into global routing paths, which it stores in a global routing storage structure. After that, the process determines whether it has generated detail routes for all the sub-regions of the IC region. If yes, the process ends; if no, repeating the above processes.

The conventional arts include common layout optimization/correction techniques such as via doubling, wire spreading, and correction by moving edges incrementally to meet recommended rules. However, these techniques have been applied by layout designers manually.

### SUMMARY OF THE DISCLOSURE

Unlike the prior arts doing the layout optimization/correction techniques by layout designers manually, the present invention provides a software tool used to optimize the routing design by means of a layout database. The method has a fist step of inputting data to define one or more than one layout violations, thereby the layout violations are detected and which are automatically optimized/corrected/fixed.

According to the preferred embodiment of the present invention, firstly, the software tool loads the layout database, and then the tool goes through each routing layer from bottom to top layer to check, identify and mark the violation(s) in order. After that, the tool computes a cost of the correction based on order and violation propagation, and performs the correction or fix. Subsequently, to repeat the above steps until there is no violation.

In particular, the layout database is adopted to pass the Design Rule Checks or to go through the Resolution Enhancement Technologies steps. The method further goes to detect and mark the layout violation(s), and to order the layout violation(s) according to assigned weight and the cost recorded in the layout database in an exemplary embodiment.

The mentioned weight of the violation(s) is in proportion to the amount of violation(s) with regard to the calculation method that determines the violation. In other case, the weight is an edge placement error (EPE) obtained from an aerial image simulation, or an edge placement error obtained from a resist image simulation, or an edge placement error obtained from a lithography simulation including an aerial image, a resist image, a post-exposure bake, develop and etching.

According to another embodiment of the present invention, the software tool is used to perform the layout violations or enhancements, the tool has the following steps of loading a layout database firstly, then going through each routing layer from bottom to top layer, detecting and marking one or more than one layout violations, translating the violation(s) into blockage(s) in current routing layer, rip-up all nets involved in violation(s) according to a selection strategy, ordering the un-routed nets according to routability or total amount of violation or absolute amount of violation(s), and re-routing all un-routed nets in the selected order.

The selection strategy of the preferred embodiment has a step of defining one or more than one non-preferred routing directions, a step of defining one or more than one preferred routing direction, and a step of defining one or more than one vias for alternative routing layer(s). More, the step is further to rip-up more nets and re-order, re-route if necessary to accomplish the IC layout.

### BRIEF DESCRIPTION OF DRAWINGS

The foregoing aspects and many of the attendant advantages of this invention will be more readily appreciated as the same becomes better understood by reference to the following detailed description, when taken in conjunction with the accompanying drawings, wherein:

The present invention will be readily understood by the following detailed description in conjunction accompanying drawings, in which:

FIG. 1 illustrates an example of an IC layout of the prior art;

FIGS. 2 and 3 illustrate two layers of 16 partitions of an IC region of the prior art;

FIG. 4 shows a full chip layout divided equally into 16 partitions of the present invention;

FIG. 5 shows an example of layout violation of the present invention;

FIGS. 6-11 shows a scheme to correct/fix the routing violation in FIG. 5;

FIG. 12 shows a routing window with grid in both vertical and horizontal direction of the present invention;

FIGS. 13-15 shows a scheme to correct/fix the routing violation in FIG. 12;

FIG. 16 shows a scheme to correct/fix the routing violation, which is a via-doubling requirement of the present invention;

FIGS. 17A-17C illustrate a preferred way to correct a violation by using additional knowledge of the present invention;

FIG. 18 shows the flowchart of the scheme of Edge Moving Procedure of the present invention;

FIG. 19 shows the steps of the above strategy of the present invention;

FIG. 20 shows the flowchart of the scheme of Rip-up and re-route Procedure of the present invention;

FIG. 21 shows a flowchart of the method for integrated circuit layout optimization of the present invention;

FIG. 22 shows a preferred embodiment of the present invention;

FIG. 23 shows the steps of the method for integrated circuit layout optimization using a software tool of the present invention;

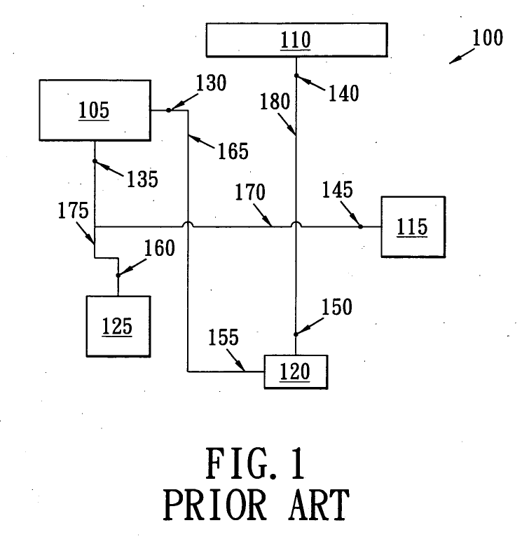

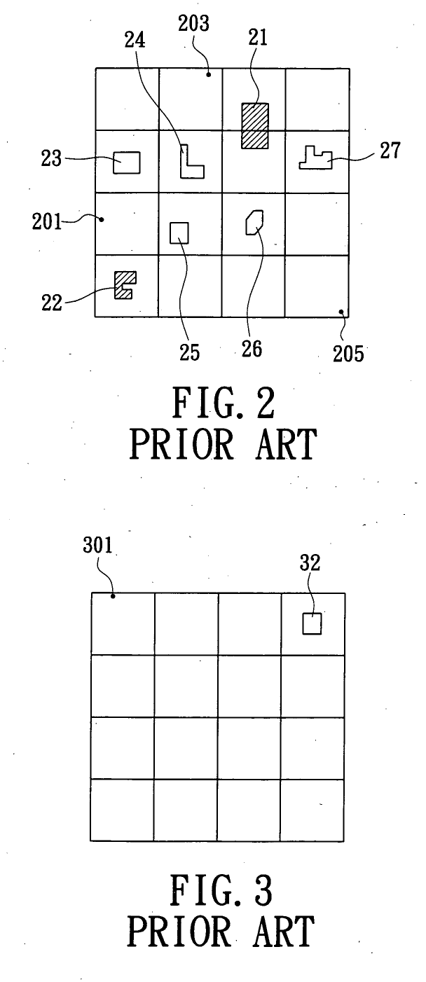

### DETAILED DESCRIPTION OF THE PREFERRED EMBODIMENTS

The present invention is directed towards a method and an apparatus for integrated circuit layout optimization. For further understanding of the invention, please refer to the following detailed description illustrating the embodiments and examples of the invention. However, one of ordinary skill in the art will realize that the invention may be practiced without the use of these specific details. In other instances, well-known structures and devices are shown in block diagram form in order not to obscure the description of the invention with unnecessary detail.

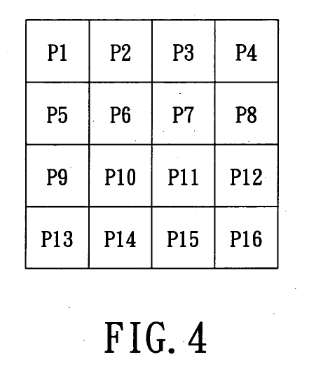

In the preferred embodiment of the present invention, it is advantageous to divide the full chip into smaller size of pieces (partitions) for a large size chip. Each partition is a processing window to perform layout optimization/correction/fix. FIG. 4 shows a full chip layout divided equally into 16 partitions, labeled P1, P2, P3, P4, P5, P6, P7, P8, P9, P10, P11, P12, P13, P14, P15 and P16. The order of processing these partitions can be in several different ways:

Firstly, a row-major order is disclosed.

Starting from the top-left corner P1, the processing window moves from left to right at the top row. Once the top row is processed, the window moves to the second row and start from left to right again. This procedure is repeated until the whole chip is processed. The sequence is P1, P2, P3, P4, P5, P6, P7, P8, P9, P1, P11, P12, P13, P14, P15 and P16.

Secondly, a column-major order is disclosed.

Starting from the top-left corner P1, the window moves down toward bottom of the first column. The window then moves into the second column. This procedure is repeated until the whole chip is processed. The sequence is P1, P5, P9, P13, P2, P6, P10, P14, P3, P7, P11, P15, P4, P8, P12 and P16.

Thirdly, an example of wave propagation is disclosed.

Starting from the top-left corner P1, the window moves to process all P1's neighbors P2 and P5. It then moves to process all neighbors of P2 and P5. This procedure is repeated until the whole chip is processed. The sequence is P1, P2 P5, P3, P6, P9, P4, P7, P10, P13, P8, P11, P14, P12, P15 and P16.

It should be easy to understand that in the above schemes, the starting point need not to be fixed to P1. The other three corners P4, P13, P16 can also be the starting point. The spirit of the present invention can also be easily applied to any begin with any of the other partitions. It is also beneficial to pre-process the whole chip and count the violations contained inside each partition. The processing order follows the number of violations inside the partitions. For example, the partition that has the highest number of violations is processed first, followed by the one with the next highest number of violations.

It is beneficial to make the processing window slightly larger than the partition. This makes the bordering areas processed by two different windows. Thus minimize potentially shortfalls due to abrupt change in the borders (boundary conditions) and improve the quality of results.

Basic operations for layout correction usually are done by removing conflicting routing elements such as metal wires and/or vias out of the violation region. The basic operations for layout optimization/correction/fix include the following:
1) Metal widening, that is to simply widen the width of a metal wire;
2) Via insertion and use alternative routing layer, that is to insert vias to move signal to the next layer and complete the route there;
3) Edge Moving, that is to move the edge or segment of a wire away from violation zone. Various options available in moving an edge, such as a) move out minimal distance away from violation zone; b) move away to the next grid; c) move away from violation as much as possible to allow room for subsequent correction operations; d) move away in one direction only; move away for two directions;
4) Rip-up and Re-Route, that is to delete the current route of selected nets, and add new routing constraints based on violations, after that, it is to re-route the rip-up nets to optimize/correct/fix layout.

Nevertheless, any one of the operations can cause new violations. Subsequent operations are required to correct/fix these violations.

The present invention is to solve the major challenges in building integrated circuits (IC) at sub-wavelength geometries to ensure the design intent faithfully transferred onto silicon; to ensure the design is manufacturable, or with acceptable yield subject to process variations. Therefore, the method to process a layout database to optimize or correct or fix layout violations or enhancements is provided. The layout violations are identified through various means such as design rules, recommended rules, timing/signal integrity/power constraints, lithography rules, Resolution Enhancement Technologies (RET) requirements and preferences, and process and manufacturing constraints. Particularly, a software tool is used to optimize the routing design by means of a layout database.

Some examples show the schemes of the integrated circuit layout optimization, as follows:

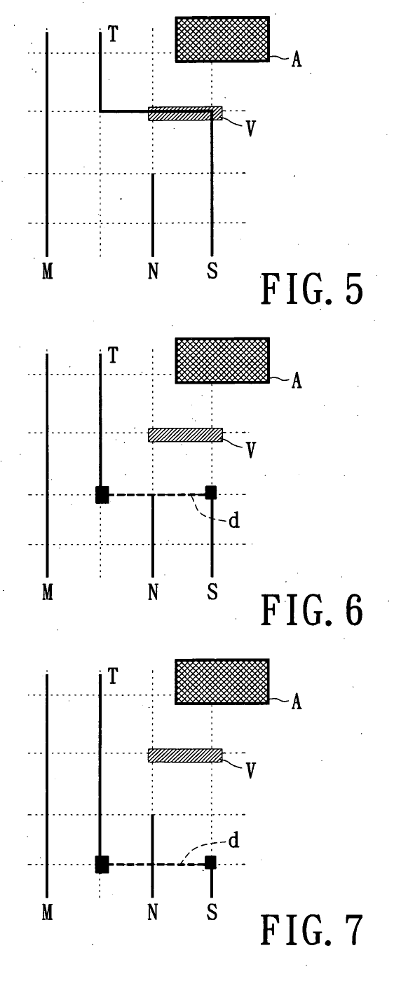

An example of layout violation is shown in FIG. 5. A routing region is shown with an underlying vertical and horizontal grid system. The vertical grid along the virtual lines is the preferred routing direction for the current layer while the horizontal grid is non-preferred. There also exists an alternative routing layer where the horizontal direction is preferred over vertical direction. There are three nets partly contained this routing region identified by M, N and the net ST. The aggressor “A” causes a violation in part of net ST, and the violation region is denoted as “V”. Note that the segment in the violation region is running in the non-preferred direction (horizontal) in current routing layer.

FIG. 6 shows a scheme to correct/fix the routing violation in FIG. 5. The violating segment of net ST is moved away from the violation region V thus to eliminate the layout violation. Vias are inserted to allow part of connection to be done in alternative layer, as shown in dotted line (d). Note that the routing in alternative layer is in its preferred direction.

FIG. 7 shows a scheme to correct/fix the routing violation in FIG. 5. The correction is similar to the embodiment of FIG. 6 except that the violating segment is moved farther away from the violation region V. This way, a different routing track in the alternative layer is used. In some situation, this can avoid conflicts in the alternative routing layer.

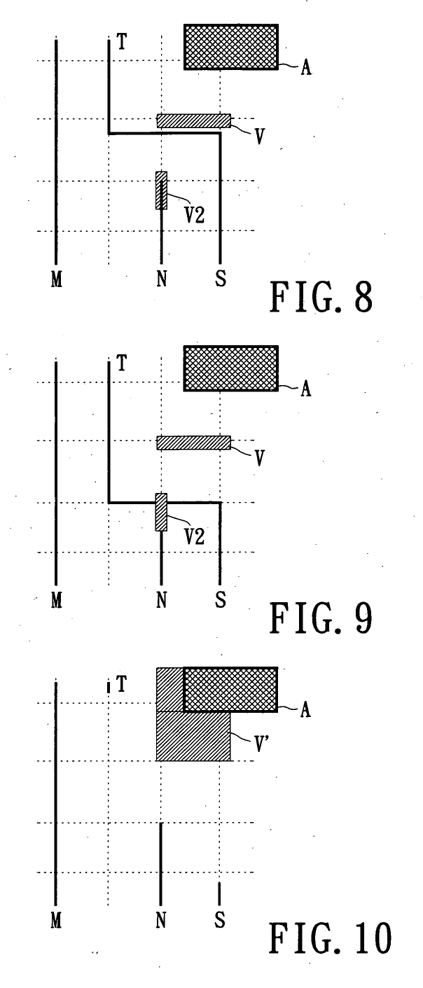

FIG. 8 shows a scheme to correct/fix the routing violation in FIG. 5. The violating segment is moved out of the violation region V with just enough room to clear the violation. The segment is still on a non-preferred direction of the current layer. Due to the new location of said segment, a new violation with respect to net N is created. Further layout optimization is required to clear this violation. Note that it is possible to create more violations when trying to correct violation region V2. The process thus can propagate and affect to a large set of nets. The optimization/correction process cannot stop until all violations are corrected.

FIG. 9 shows a scheme to correct/fix the routing violation in FIG. 5. The correction is similar to that of FIG. 8. However, the violating segment, although in non-preferred direction, is moved to the next grid, but another violation region V2 is created with respect to net N.

FIG. 10 shows a scheme to correct/fix the routing violation in FIG. 5. The violation region V′ is translated into a routing blockage. The entire net of net ST deleted from this routing region V′ leaving its start and end terminals S and T. Net ST is then being routed again given this new blockage. This re-routing process is usually done by an automatic router although manual route is still possible.

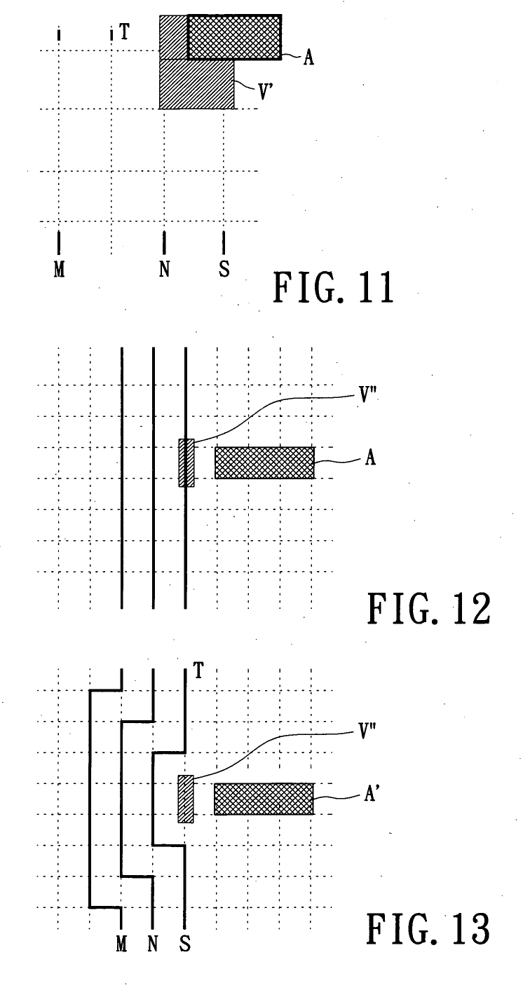

FIG. 11 shows a scheme to correct/fix the routing violation in FIG. 5. This scheme is similar to which shown in FIG. 10 except that more nets are deleted from the routing. In this embodiment, all three nets (M, N, ST) in this routing region are deleted and need to be re-routed. This scheme gives the re-routing process more flexibility and thus higher probability to implement.

FIG. 12 shows a routing window with grid in both vertical and horizontal direction. The preferred direction for current routing layer is vertical. Three wires run vertically with a violation region V″ in part of net ST caused by aggressor A′.

FIG. 13 shows a scheme to correct/fix the routing violation in FIG. 12. Part of net ST is moved to next grid to avoid the violation region V″. The moved out portion of net ST causes violation in its neighbor net N and thus a new route for net N is created, which in turn causes a violation in net M and its new route. Such a correction is best when there is a spare track in the vicinity of the original violating track and the propagation of violation is limited.

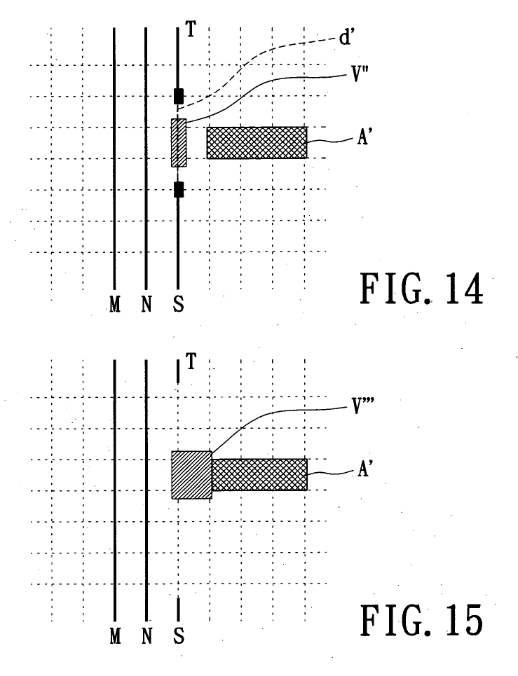

FIG. 14 shows a scheme to correct/fix the routing violation in FIG. 12. Vias are inserted to switch the violating segment of net ST into alternative routing layer to correct the violation. Note that the routing in the alternative layer is in non-preferred direction. The new segment in the alternative layer may cause new violations which need to be corrected too. Thus the possibility of violation propagation is pushed to a different layer, such as the part of the shown dotted line (d′).

FIG. 15 shows a scheme to correct/fix the routing violation in FIG. 12. The violating net ST is deleted from routing. A blockage area is inserted to represent the original violation region V′″. The re-route of net ST can be either done manually or by an automatic router. In both cases, an alternative routing solution is sought to correct/fix the routing violation.

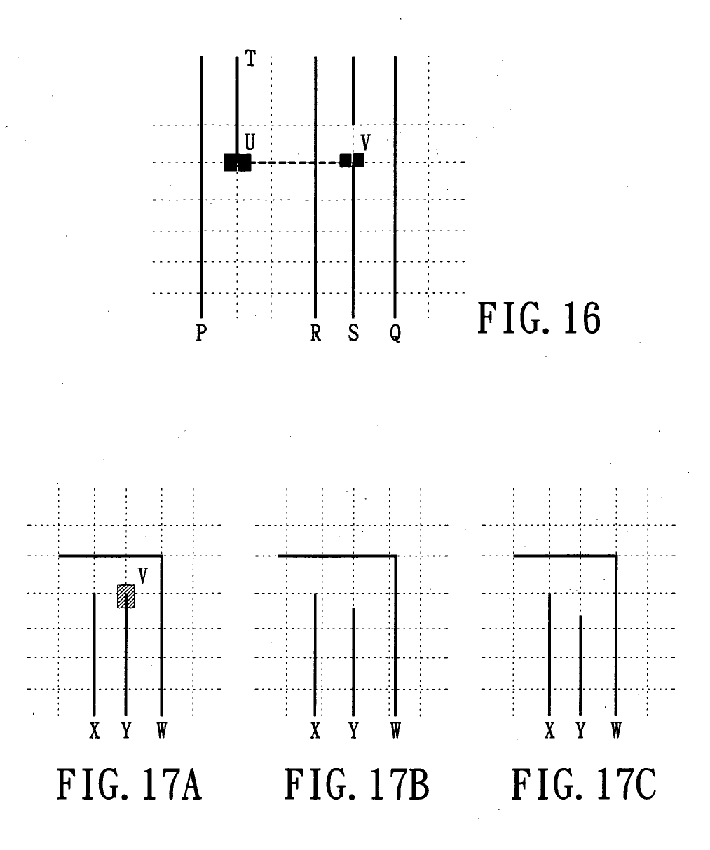

FIG. 16 shows a scheme to correct/fix the routing violation, which is a via-doubling requirement. Double vias are inserted at both U and V location. This correction leads to new violations regions on wires P, R and Q. Subsequent corrections are needed to remove these new violations.

Unfortunately, there are usually many layout violations existed in a correction window. There is still a certain cost to correct each violation. The cost factors for correction include, but not limited to, the following:
1) area in the preferred routing direction at current routing layer;
2) area in the non-preferred routing direction at current routing layer'
3) number of vias inserted;
4) area in the preferred routing direction at the next level routing layer;
5) area in the non-preferred routing direction at the next level routing layer;
6) cost and number of new violations created due to the correction of current violation.

For example, the process of selecting a correction method with lower cost:

FIGS. 17A through 17C illustrate a preferred way to correct a violation by using additional knowledge. In FIG. 17A, the violation region V is caused by the extra spacing requirement between the three wires X, Y and W.

FIG. 17B shows a straightforward way to correct the violation. Wires X and W are both moved slightly away from wire Y (apart from the virtual lines), which is also shorten to avoid the violation region V. The moving of wires X and W, though is small, may cause new violations to other wires not shown here since the routing is based on grid. Thus the cost of this correction method is high.

FIG. 17C shows another correction scheme. Wire Y is shortened to avoid violation region V. While the spacing between X, Y and W are maintained. This is due to the knowledge that violations between parallel run wires can be fixed in OPC stage with the insertion of scattering bars (also called sub-resolution assist features). And thus it is not necessary to move wires X and W off grid and away from wire Y. No further violations are created and thus the correction is low.

Furthermore, the present invention provides the schemes to optimize /correct/fix layout, which include the step for edge moving and the step for rip-up re-routing.

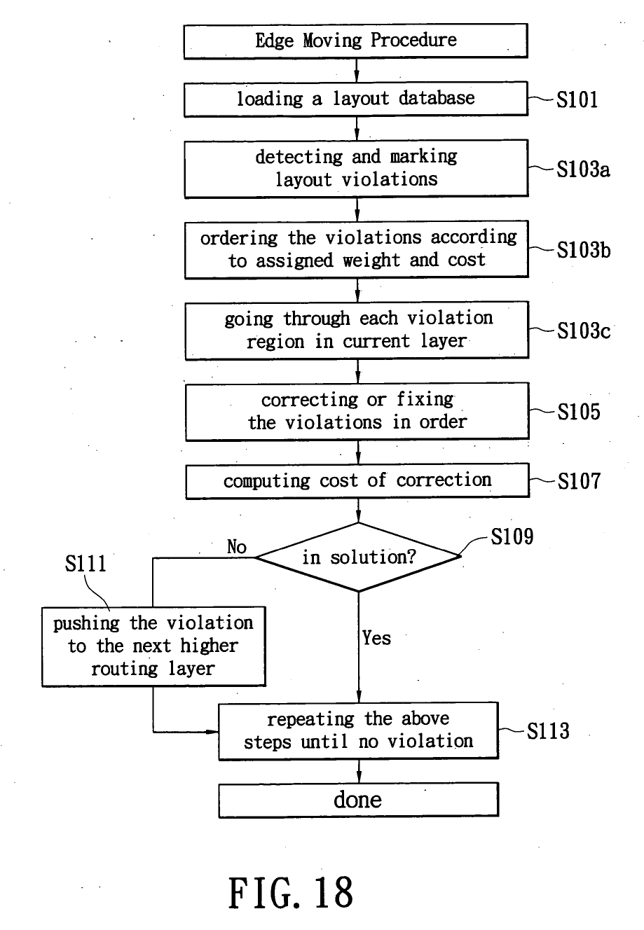

FIG. 18 shows the flowchart of the scheme of Edge Moving Procedure:

At first, a software tool loads a layout database (step S101). For example, this layout database is adopted to pass the Design Rule Checks or go through the Resolution Enhancement Technologies steps in a preferred embodiment.

After that, the routing step goes through each routing layer from bottom to top layer (step S103). In this routing step, every layout violation is detected and marked for each rule and model described in the present invention (step S103a); and the violations are ordered according to assigned weight and cost recorded in the layout database (step S103b); afterward, the routing process goes through each violation region in current layer (step S103c).

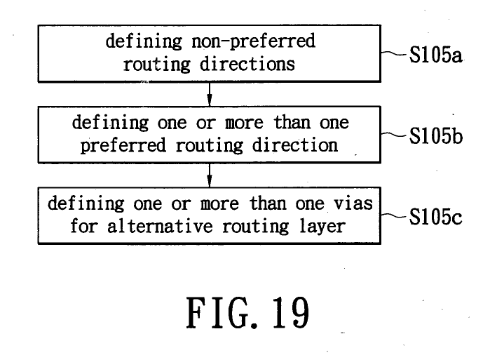

Next, this routing process is to correct or fix the violations in order according to a strategy selected from below (step S105). Referring to FIG. 19 which shows the steps of the above strategy, including the steps of defining one or more than one non-preferred routing directions (step S105a); and defining one or more than one preferred routing direction (step S105b); and defining one or more than one vias for alternative routing layer(s) (step S105c). Where the violation is removed by switching the signal to the alternative routing layer, which is the one immediate above the current routing layer.

Next step in FIG. 18, the routing process is to compute cost of correction based on order and violation propagation (step S107).

Next, the routing process is to check, identify and mark the violation(s), and to determine whether or not the routing process is in solution (step S109). If yes, it is in solution, then the next step S115 is processed, but if no solution found, the process is to push the violation to the next higher routing layer by inserting vias at current layer and route with violation at the next layer (step S111). Afterward, it's to repeat the above steps until no violation (step S113).

Particularly, the above-mentioned weight of the violation(s) is in proportion to the amount of violation(s) with regard to the calculation method that determines the violation. More, the weight is an edge placement error (EPE) obtained from an aerial image simulation, or a resist image simulation, or a lithography simulation including the aerial image, the resist image, a post-exposure bake, develop and etching.

More, the cost used for ordering the violations includes the area in the preferred routing direction at current routing layer, and the area in the non-preferred routing direction at current routing layer, and the number of vias inserted, and the area in the preferred routing direction at the next level routing layer, and the area in the non-preferred routing direction at the next level routing layer, and the cost and number of new violations created due to the correction of current violation.

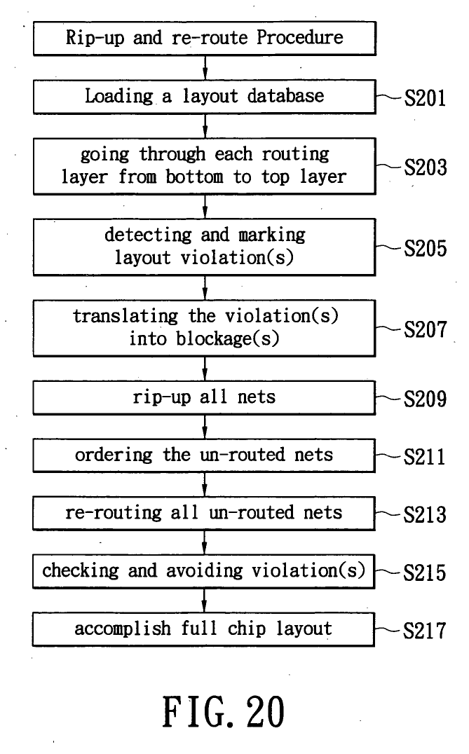

FIG. 20 shows the flowchart of the scheme of Rip-up and re-route Procedure:

In the first step, the software tool loads a layout database (step S201); and then the procedure goes through each routing layer from bottom to top layer (step S203).

Next, the procedure is to detect and mark one or more than one layout violations for each rule and for each mode described in the invention (step S205), and to translate the violation(s) into blockage(s) in current routing layer (step S207). After that, the step goes to rip-up all nets involved in violation(s) according to a selection strategy (step S209), and to order the un-routed nets according to routability or total amount of violation or absolute amount of violation(s) (step S211).

Wherein the step of rip-up all nets involved in violation(s) according to the selection strategy referring to FIG. 19, the selection has the steps of defining one or more than one non-preferred routing directions (step S105a); and defining one or more than one preferred routing direction (step S105b); and defining one or more than one vias for alternative routing layer(s) (step S105c).

Next, the procedure is to re-route all un-routed nets in the selected order (step S213) and to check and avoid violation(s) while routing nets (step S215), and to rip-up more nets and re-order, re-route if necessary to accomplish full chip (the IC) layout (step S217).

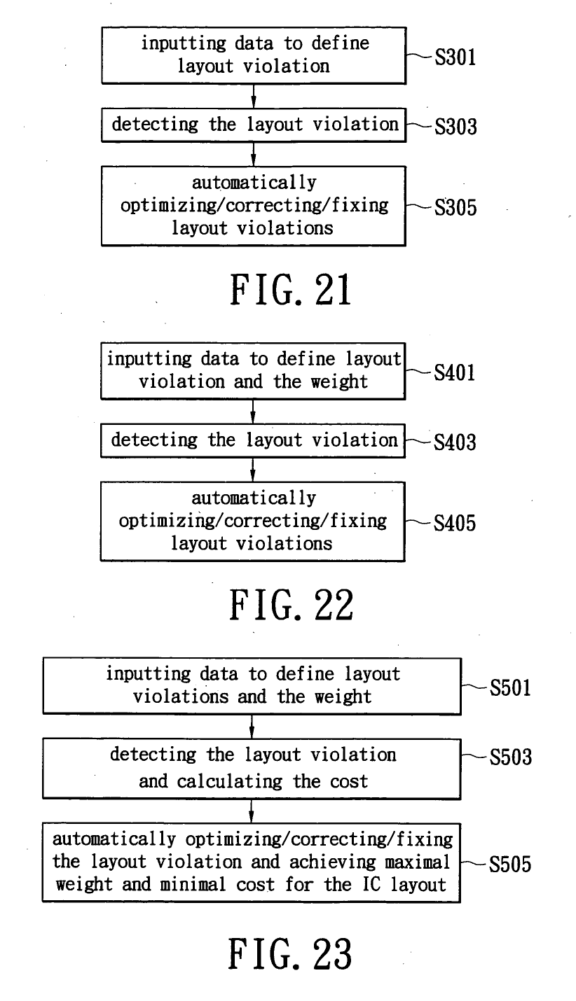

FIG. 21 shows a flowchart of the method for integrated circuit layout optimization, which is one of the preferred embodiment of the present invention. Where a software tool is used to optimize/correct/fix a layout database, the method using the software tool essentially has the steps of inputting data to define one or more than one layout violations (step S301), detecting the layout violation(s) (step S303), and automatically optimizing/correcting/fixing layout violations (step S305). Moreover, in other preferred embodiment of the present invention, the above set of steps can implement the software tool used to optimize/correct/fix a layout database of an interconnect portion, which includes the metal layers and vias.

More, the method further includes the step of correcting a design rule violation, the step of enforcing recommended design rule, the step of reducing design variability in timing, signal integrity and power resulting from manufacturing process variations, and reducing Optical Proximity Correction (OPC) effort and/or the number of sub-resolution assist features (SRAFs) added by the OPC process, the step of enforcing lithography rules, the step of reducing mask making time and/or mask data volume and/or mask inspection time, the step of increasing the size of process windows in terms of defocus and exposure dose in lithography, and the step of limiting the Critical Dimension (CD) errors and/or variations due to process variations. Moreover, the step of detecting the layout violation(s) is one of the Resolution Enhancement technologies (RET), which includes Optical Proximity Correction (OPC) and Phase-Shifted Mask (PSM). Particularly, the step of detecting the layout violation(s) is an aerial image simulation. The step of detecting the layout violation is a full lithographic simulation including an aerial image, a resist image, a post exposure bake, developing and etching. The step of automatically optimizing/correcting/fixing layout violations further includes the step to rip-up the nets involved in the violation(s), and add new routing constraints from the violation(s) and re-route the nets. The aforementioned steps are not only implemented in the method shown in FIG. 21, but can be implemented on the other embodiments described below.

As shown in FIG. 22, which is a preferred embodiment of the present invention. The software tool of the method is used to optimize/correct/fix a layout database, wherein the software tool implements the steps of inputting data to define one or more than one layout violations and the weight to fix each violation (step S401); and detecting the layout violation(s) (step S403), and automatically optimizing/correcting/fixing layout violations to achieve maximize weight for the integrated circuit layout (step S405). The weight of the violation(s) is in proportion to the amount of violation(s) with regard to the calculation method that determines the violation. Moreover, in other preferred embodiment of the present invention, the above set of steps can implement the software tool used to optimize/correct/fix a layout database of an interconnect portion, which includes the metal layers and vias.

FIG. 23 shows the steps of the method for integrated circuit layout optimization using a software tool to optimize/correct/fix a layout database. The software tool uses the following steps to establish the layout database, including the step of inputting data to define one or more than one layout violations and the weight to fix each violation (step S501), and the step of detecting the layout violation(s) and calculating the cost to optimize/correct/fix each violation (step S503), and the step of automatically optimizing/correcting/fixing the layout violation(s) and achieving maximal weight and minimal cost for the IC layout (step S505). Moreover, in other preferred embodiment of the present invention, the above set of steps can implement the software tool used to optimize/correct/fix a layout database of an interconnect portion, which includes the metal layers and vias.

The conditions of the mentioned cost are shown in the description of FIG. 16.

The many features and advantages of the present invention are apparent from the written description above and it is intended by the appended claims to cover all. Furthermore, since numerous modifications and changes will readily occur to those skilled in the art, it is not desired to limit the invention to the exact construction and operation as illustrated and described. Hence, all suitable modifications and equivalents may be resorted to as falling within the scope of the invention.

What is claimed is:

1. A method for integrated circuit layout optimization, wherein a software tool is used to perform the layout optimizations, corrections or enhancements, comprising:
loading a layout database;
going through each routing layer from bottom to top layer;
checking, identifying and marking the violation(s);
computing a cost of the correction based on order and violation propagation;
perform the correction or fix; and
repeating the above method until there is no violation.

2. The method of claim 1, wherein the layout database is adopted to pass the Design Rule Checks.

3. The method of claim 1, wherein the layout database is adopted to go through the Resolution Enhancement Technologies steps.

4. The method of claim 1, wherein the step of going through each routing layer from bottom to top layer includes the steps of:
1) detecting and marking the layout violation(s);
2) ordering the layout violation(s) according to assigned weight and the cost recorded in the layout database; and
3) going through each violation region in current layer.

5. The method of claim 4, wherein the weight of the violation(s) is in proportion to the amount of violation(s) with regard to the calculation method that determines the violation.

6. The method of claim 4, wherein the weight is an edge placement error (EPE) obtained from an aerial image simulation.

7. The method of claim 4, wherein the weight is an edge placement error (EPE) obtained from a resist image simulation.

8. The method of claim 4, wherein the weight is an edge placement error (EPE) obtained from a lithography simulation including an aerial image, a resist image, a post-exposure bake, develop and etching.

9. The method of claim 4, wherein the cost includes:
1) area in the preferred routing direction at current routing layer;
2) area in the non-preferred routing direction at current routing layer;
3) number of vias inserted;
4) area in the preferred routing direction at the next level routing layer;
5) area in the non-preferred routing direction at the next level routing layer; and
6) cost and number of new violations created due to the correction of current violation.

10. The method of claim 1, wherein the step of correcting or fixing the violation(s) in order is in accordance with a strategy selected from:
1) a step of defining one or more than one non-preferred routing directions;
2) a step of defining one or more than one preferred routing direction; and
3) a step of defining one or more than one vias for alternative routing layer(s).

11. The method of claim 10, wherein the violation is removed by switching signal to the alternative routing layer.

12. The method of claim 10, wherein the alternative routing layer is the one immediate above the current routing layer.

13. The method of claim 1, wherein after the step of checking, identifying and marking the violation(s), the method then determines whether or not it is in solution, if no solution is found, the method is to push the violation to the next higher routing layer by inserting vias at current layer and route with violation at the next layer.

14. A method for integrated circuit layout optimization, wherein a software tool is used to perform the layout violations or enhancements, comprising:
loading a layout database;
going through each routing layer from bottom to top layer;
detecting and marking one or more than one layout violations;
translating the violation(s) into blockage(s) in current routing layer;
rip-up all nets involved in violation(s) according to a selection strategy;
ordering the un-routed nets according to routability or total amount of violation or absolute amount of violation(s); and
re-routing all un-routed nets in the selected order.

15. The method of claim 14, wherein the selection strategy has:
1) a step of defining one or more than one non-preferred routing directions;
2) a step of defining one or more than one preferred routing direction; and
3) a step of defining one or more than one vias for alternative routing layer(s).

16. The method of claim 15, wherein the violation is removed by switching signal to the alternative routing layer.

17. The method of claim 15, wherein the alternative routing layer is the one immediate above the current routing layer.

18. The method of claim 14, wherein further including a step of checking and avoiding violation(s) is processed after the step of re-routing all un-routed nets.

19. The method of claim 14, wherein the step is further to rip-up more nets and re-order, re-route if necessary to accomplish the IC layout.

20. A method for integrated circuit layout optimization, wherein a software tool is used to optimize/correct/fix a layout database, comprising:
1) inputting data to define one or more than one layout violations;
2) detecting the layout violation(s); and
3) automatically optimizing/correcting/fixing layout violations.

21. The method of claim 20, further including:
1) correcting a design rule violation;
2) enforcing recommended design rule;
3) reducing design variability in timing, signal integrity and power resulting from manufacturing process variations;
4) reducing Optical Proximity Correction (OPC) effort and/or the number of sub-resolution assist features (SRAFs) added by the OPC process;
5) enforcing lithography rules;
6) reducing mask making time and/or mask data volume and/or mask inspection time;
7) increasing the size of process windows in terms of defocus and exposure dose in lithography; and
8) limiting the Critical Dimension (CD) errors and/or variations due to process variations.

22. The method of claim 20, wherein the step of detecting the layout violation(s) is one of the Resolution Enhancement technologies (RET) including Optical Proximity Correction (OPC) and Phase-Shifted Mask (PSM).

23. The method of claim 20, wherein the step of detecting the layout violation(s) is an aerial image simulation.

24. The method of claim 20, wherein the step of detecting the layout violation is a full lithographic simulation including an aerial image, a resist image, a post exposure bake, developing and etching.

25. The method of claim 20, wherein the step of automatically optimizing/correcting/fixing layout violations further includes a step to rip-up the nets involved in the violation(s), add new routing constraints from the violation(s) and re-route the nets.

26. A method for integrated circuit layout optimization, wherein a software tool is used to optimize/correct/fix a layout database, comprising:
1) inputting data to define one or more than one layout violations and the weight to fix each violation;
2) detecting the layout violation(s); and
3) automatically optimizing/correcting/fixing layout violations to achieve maximize weight for the integrated circuit layout.

27. The method of claim 26, further including:
1) correcting a design rule violation;
2) enforcing recommended design rule;
3) reducing design variability in timing, signal integrity and power resulting from manufacturing process variations;
4) reducing Optical Proximity Correction (OPC) effort and/or the number of sub-resolution assist features (SRAFs) added by OPC process;
5) enforcing lithography rules;
6) reducing mask making time and/or mask data volume and/or mask inspection time;
7) increasing the size of process windows in terms of defocus and exposure dose in lithography system; and
8) limiting the Critical Dimension (CD) errors and/or variation(s) due to process variations.

28. The method of claim 26, wherein the step of detecting the layout violation(s) is one of the Resolution Enhancement technologies (RET) including Optical Proximity Correction (OPC) and Phase-Shifted Mask (PSM).

29. The method of claim 26, wherein the step of detecting the layout violation(s) is through aerial image simulation.

30. The method of claim 26, wherein the step of detecting the layout violation(s) is through a full lithographic simulation including an aerial image, a resist in image, developing and etching.

31. The method of claim 26, wherein the weight of the violation(s) is in proportion to the amount of violation(s) with regard to the calculation method that determines the violation.

32. The method of claim 26, wherein the weight is an edge placement error (EPE) obtained from an aerial image simulation.

33. The method of claim 26, wherein the weight is an edge placement error (EPE) obtained from a resist image simulation.

34. The method of claim 26, wherein the weight is an edge placement error (EPE) obtained from a lithography simulation including an aerial image, a resist image, a post-exposure bake, develop and etching.

35. The method of claim 26, wherein the step of automatically optimizing/correcting/fixing layout violations further includes step to rip-up the nets involved in the violation(s), add new routing constraints from the violation(s) and re-route the nets.

36. A method for integrated circuit layout optimization, wherein a software tool is used to optimize/correct/fix a layout database, comprising:
1) inputting data to define one or more than one layout violations and the weight to fix each violation;
2) detecting the layout violation(s) and calculating the cost to optimize/correct/fix each violation; and
3) automatically optimizing/correcting/fixing the layout violation(s) and achieving maximal weight and minimal cost for the IC layout.

37. The method of claim 36, further including:
1) correcting a design rule violation;
2) enforcing recommended design rule;
3) reducing design variability in timing, signal integrity and power resulting from manufacturing process variations;
4) reducing Optical Proximity Correction (OPC) effort and/or the number of sub-resolution assist features (SRAFs) added by OPC process;
5) enforcing lithography rules;
6) reducing mask making time and/or mask data volume and/or mask, inspection time;
7) increasing the size of process windows in terms of defocus and exposure dose in lithography system; and
8) limiting the Critical Dimension (CD) errors and/or variation(s) due to process variations.

38. The method of claim 36, wherein the step of detecting the layout violation(s) is one of the Resolution Enhancement technologies (RET) including Optical Proximity Correction (OPC) and Phase-Shifted Mask (PSM).

39. The method of claim 36, wherein the step of detecting the layout violation(s) is through aerial image simulation.

40. The method of claim 36, wherein the step of detecting the layout violation(s) is through a full lithographic simulation including an aerial image, a resist in image, developing and etching.

41. The method of claim 36, wherein the weight of the violation(s) is in proportion to the amount of violation(s) with regard to the calculation method that determines the violation.

42. The method of claim 36, wherein the weight is an edge placement error (EPE) obtained from an aerial image simulation.

43. The method of claim 36, wherein the weight is an edge placement error (EPE) obtained from a resist image simulation.

44. The method of claim 36, wherein the weight is an edge placement error (EPE) obtained from a lithography simulation including an aerial image, a resist image, a post-exposure bake, develop and etching.

45. The method of claim 36, wherein the cost includes:
1) area in the preferred routing direction at current routing layer;
2) area in the non-preferred routing direction at current routing layer;
3) number of vias inserted;
4) area in the preferred routing direction at the next level routing layer;
5) area in the non-preferred routing direction at the next level routing layer; and
6) cost and number of new violations created due to the correction of current violation.

46. The method of claim 36, wherein the step of automatically optimizing/correcting/fixing layout violations further includes step to rip-up the nets involved in the violation(s), add new routing constraints from the violation(s) and re-route the nets.

47. A method for integrated circuit layout optimization, wherein a software tool is used to optimize/correct/fix a layout database of an interconnect portion having metal layers and vias, comprising:
1) inputting data to define one or more than one layout violations;
2) detecting the layout violation(s); and
3) automatically optimizing/correcting/fixing layout violation(s).

48. The method of claim 47, further including:
1) correcting a design rule violation;
2) enforcing recommended design rule;
3) reducing design variability in timing, signal integrity and power resulting from manufacturing process variation(s);
4) reducing Optical Proximity Correction (OPC) effort and/or the number of sub-resolution assist features (SRAFs) added by the OPC process;
5) enforcing lithography rules;
6) reducing mask making time and/or mask data volume and/or mask inspection time;
7) increasing the size of process windows in terms of defocus and exposure dose in lithography; and
8) limiting the Critical Dimension (CD) errors and/or variations due to process variations.

49. The method of claim 47, wherein the step of detecting the layout violation(s) is one of the Resolution Enhancement technologies (RET) including Optical Proximity Correction (OPC) and Phase-Shifted Mask (PSM).

50. The method of claim 47, wherein the step of detecting the layout violation(s) is aerial image simulation.

51. The method of claim 47, wherein the step of detecting the layout violation is a full lithographic simulation including an aerial image, a resist image, a post exposure bake, developing and etching.

52. The method of claim 47, wherein the step of automatically optimizing/correcting/fixing layout violations further includes step to rip-up the nets involved in the violation(s), add new routing constraints from the violation(s) and re-route the nets.

53. A method for integrated circuit layout optimization, wherein a software tool is used to optimize/correct/fix a layout database of an interconnect portion having metal layers and vias, comprising:
1) inputting data to define one or more than one layout violations and the weight to fix each violation;
2) detecting the layout violation(s); and
3) automatically optimizing/correcting/fixing layout violations to achieve maximize weight for the integrated circuit layout.

54. The method of claim 53, further including:
1) correcting a design rule violation;
2) enforcing recommended design rule;
3) reducing design variability in timing, signal integrity and power resulting from manufacturing process variations;
4) reducing Optical Proximity Correction (OPC) effort and/or the number of sub-resolution assist features (SRAFs) added by OPC process;
5) enforcing lithography rules;
6) reducing mask making time and/or mask data volume and/or mask inspection time;
7) increasing the size of process windows in terms of defocus and exposure dose in lithography system; and
8) limiting the Critical Dimension (CD) errors and/or variation(s) due to process variations.

55. The method of claim 53, wherein the step of detecting the layout violation(s) is one of the Resolution Enhancement technologies (RET) including Optical Proximity Correction (OPC) and Phase-Shifted Mask (PSM).

56. The method of claim 53, wherein the step of detecting the layout violation(s) is through aerial image simulation.

57. The method of claim 53, wherein the step of detecting the layout violation(s) is through a full lithographic simulation including an aerial image, a resist in image, developing and etching.

58. The method of claim 53, wherein the weight of the violation(s) is in proportion to the amount of violation(s) with regard to the calculation method that determines the violation.

59. The method of claim 53, wherein the weight is an edge placement error (EPE) obtained from an aerial image simulation.

60. The method of claim 53, wherein the weight is an edge placement error (EPE) obtained from a resist image simulation.

61. The method of claim 53, wherein the weight is an edge placement error (EPE) obtained from a lithography simulation including an aerial image, a resist image, a post-exposure bake, develop and etching.

62. The method of claim 53, wherein the step of automatically optimizing/correcting/fixing layout violations further includes step to rip-up the nets involved in the violation(s), add new routing constraints from the violation(s) and re-route the nets.

63. A method for integrated circuit layout optimization, wherein a software tool is used to optimize/correct/fix a layout database of an interconnect portion having metal layers and vias, comprising:
1) inputting data to define one or more than one layout violations and the weight to fix each violation;
2) detecting the layout violation(s) and calculating the cost to optimize/correct/fix each violation; and
3) automatically optimizing/correcting/fixing the layout violation(s) and achieving maximal weight and minimal cost for the IC layout.

64. The method of claim 63, further including:
1) correcting a design rule violation;
2) enforcing recommended design rule;
3) reducing design variability in timing, signal integrity and power resulting from manufacturing process variations;
4) reducing Optical Proximity Correction (OPC) effort and/or the number of sub-resolution assist features (SRA-Fs) added by OPC process;
5) enforcing lithography rules;
6) reducing mask making time and/or mask data volume and/or mask inspection time;
7) increasing the size of process windows in terms of defocus and exposure dose in lithography system; and
8) limiting the Critical Dimension (CD) errors and/or variation(s) due to process variations.

65. The method of claim 63, wherein the step of detecting the layout violation(s) is one of the Resolution Enhancement technologies (RET) including Optical Proximity Correction (OPC) and Phase-Shifted Mask (PSM).

66. The method of claim 63, wherein the step of detecting the layout violation(s) is through aerial image simulation.

67. The method of claim 63, wherein the step of detecting the layout violation(s) is through a full lithographic simulation including an aerial image, a resist in image, developing and etching.

68. The method of claim 63, wherein the weight of the violation(s) is in proportion to the amount of violation(s) with regard to the calculation method that determines the violation.

69. The method of claim 63, wherein the weight is an edge placement error (EPE) obtained from an aerial image simulation.

70. The method of claim 63, wherein the weight is an edge placement error (EPE) obtained from a resist image simulation.

71. The method of claim 63, wherein the weight is an edge placement error (EPE) obtained from a lithography simulation including an aerial image, a resist image, a post-exposure bake, develop and etching.

72. The method of claim 63, wherein the cost includes:
1) area in the preferred routing direction at current routing layer;
2) area in the non-preferred routing direction at current routing layer;
3) number of vias inserted;
4) area in the preferred routing direction at the next level routing layer;
5) area in the non-preferred routing direction at the next level routing layer; and
6) cost and number of new violations created due to the correction of current violation.

73. The method of claim 63, wherein the step of automatically optimizing/correcting/fixing layout violations further includes step to rip-up the nets involved in the violation(s), add new routing constraints from the violation(s) and re-route the nets.
